(19) United States
(12) Patent Application Publication
(10) Pub. No.: US 2005/0101160 A1
(43) Pub. Date: May 12, 2005

(54) Silicon thin film transistors and solar cells on plastic substrates

(76) Inventors: Diwakar Garg, Emmaus, PA (US); Wendelyn A. Graham, Walingford, PA (US)

Correspondence Address: AIR PRODUCTS AND CHEMICALS, INC.;PATENT DEPARTMENT, 7201 HAMILTON BOULEVARD, ALLENTOWN, PA, 181951501, US

(21) Appl. No.: 10/984,107

(22) Filed: Nov. 9, 2004

Related U.S. Application Data
(60) Provisional application No. 60/519,507, filed on Nov. 12, 2003.

(51) Int. Cl. H01L 21/26; H01L 21/20; H01L 21/00

(52) U.S. Cl. 438/795; 438/486; 438/166

(57) ABSTRACT

Method for fabricating a silicon-containing film which comprises depositing a thin film of amorphous silicon on a substrate by a plasma-enhanced chemical vapor deposition process in a reaction chamber and converting at least a portion of the amorphous silicon to crystalline silicon by irradiating the film with pulsed laser energy in a hydrogen-containing atmosphere.

### CROSS-REFERENCE TO RELATED APPLICATIONS

This application claims priority to U.S. Provisional Application Ser. No. 60/519,507 filed on Nov. 12, 2003.

### BACKGROUND OF THE INVENTION

Embodiments of the present invention relate to the formation of silicon-based thin film transistors and multi-layer solar cells on plastic or other substrates.

Substantial effort has been directed in recent years to the development and manufacture of flat panel displays. Among the emerging technologies for flat panel displays, active matrix-liquid crystal display (AM-LCD) holds the majority share of the flat panel display market today. AM-LCDs have a thin-film transistor (TFT) switch at each pixel. These active matrix thin film transistors are currently fabricated by depositing amorphous silicon on substrates such as glass and plastics capable of handling high temperatures such as KAPTON. The amorphous silicon material is ideal for this application because of its low cost, low reverse leakage current, and adequate charging current capabilities. However, as the display size and resolution increase, it will be difficult for amorphous silicon TFTs to meet requirements for pixel charging time because of low electron and hole mobilities inherent to this material.

To overcome the electron and hole mobility limitation of amorphous silicon TFTs, researchers have been developing new technologies based on crystalline silicon TFTs. The term “crystalline” as used herein is interchangeable with the terms “microcrystalline” or “polycrystalline” and all three may be used equivalently in this specification. Polycrystalline silicon has been known to have higher electron and hole mobilities than amorphous silicon. Unfortunately, the leakage current of polycrystalline silicon TFTs is significantly higher than that of amorphous silicon TFTs, creating a problem with charge leakage of the pixel (reverse leakage current) and, consequently, image fading.

A method for fabricating silicon TFTs, which have the advantages of both amorphous silicon and polycrystalline silicon, is disclosed in U.S. Pat. No. 5,773,309. The method involves selectively heating and crystallizing a top region or section of the amorphous silicon layer into polycrystalline silicon by directing pulsed energy onto the surface of amorphous silicon.

An improved method for fabricating silicon TFTs on low-temperature substrates is disclosed in U.S. Pat. No. 5,817,550. The method enables the fabrication of amorphous/polycrystalline silicon TFTs at temperatures sufficiently low to prevent damage to plastic substrates. The main steps in the improved method involve annealing the substrate at a temperature slightly above 100° C. to avoid deformation in subsequent processing steps, cleaning the surface of the plastic substrate with a solvent or an acid, depositing a thin insulating layer on the substrate at low-temperature (at or below 100° C.) by sputtering or PECVD, depositing amorphous silicon by PECVD at a temperature of about 100° C., irradiating amorphous silicon film with one or more laser pulses to partially crystallize the amorphous silicon film, and exposing partially crystallized amorphous silicon film to low temperature PECVD hydrogenation process for a short time. A number of other steps are carried out after crystallization and hydrogenation to complete the fabrication of silicon TFTs. These steps are carried out at or below 100° C. temperature to avoid damage to plastic substrates. Although the improved process has been claimed as successful in producing amorphous/polycrystalline silicon TFTs on plastic substrates at or below 100° C. temperature, the performance of these TFTs has not been acceptable due to high leakage current.

Considerable effort has been directed in recent years to the development of thin film silicon-based solar cells on substrates capable of withstanding high temperatures such as glass and stainless steel. The amorphous silicon material is ideal for this application because of its low cost, high efficiency for absorption of solar radiation, and acceptable capability for converting solar radiation into electricity. However, there are two main drawbacks with the use of amorphous silicon for solar cell application. First, the efficiency of amorphous silicon for converting solar radiation into electricity is unstable and decreases with time. The second and most important drawback is that amorphous silicon for solar cell application is deposited at a temperature close to 200° C., making it unsuitable for low-temperature plastic substrates.

Amorphous silicon-based solar cells are produced by depositing sequentially the following layers on a glass or stainless steel substrate: a thin layer of aluminum or silver on the substrate by sputtering as a light-trapping layer, a thin layer of indium tin oxide or aluminum doped zinc oxide by sputtering as a transparent conducting oxide layer, a 10 to 100 nanometer thick amorphous silicon layer doped with phosphorous, a 20 to 1000 nanometer thick intrinsic amorphous silicon layer, a 10 to 100 nanometer thick amorphous silicon layer doped with boron, a thin layer of indium tin oxide or aluminum doped zinc oxide by sputtering as a transparent conducting oxide, and silver contact grid. All of these three doped and undoped amorphous silicon layers are deposited by PECVD using a mixture of silane (or disilane) and hydrogen or a mixture of silane (or disilane), hydrogen and argon.

Recently, researchers have overcome the problem of instability of amorphous silicon for converting solar radiation into electricity by replacing boron-doped and intrinsic amorphous silicon layers with boron-doped and intrinsic microcrystalline layers, respectively. These microcrystalline silicon layers may be deposited at a temperature close to 200° C., but this may cause problems in fabricating amorphous/microcrystalline silicon solar cells on low-temperature plastic substrates.

A method for fabricating multi-terminal solar cells on low-temperature substrates incapable of withstanding sustained processing temperatures of greater than 180° C. is disclosed in U.S. Pat. No. 5,456,763. The method involves depositing amorphous silicon by sputtering or evaporation followed by simultaneously crystallizing and doping a part of amorphous silicon by irradiating amorphous silicon film with one or more laser pulses in the presence of a dopant. Hydrogen can be incorporated into amorphous and crystalline silicon structure by introducing hydrogen into the chamber at the time the amorphous silicon is exposed to laser radiation. Although the method has been claimed to be successful in producing multi-terminal silicon solar cells on substrates incapable of withstanding sustained processing temperatures of greater than 180° C., it has not been employed or demonstrated to produce multi-terminal silicon solar cells on plastic substrates that are incapable of withstanding a temperature above about 100° C.

There is a need in the art for silicon TFTs that have the advantages of both amorphous silicon (low reverse leakage current) and polycrystalline silicon (high electron and hole mobilities) without the disadvantages of polycrystalline silicon (high reverse leakage current) TFTs. In addition, there is a need for the formation of silicon TFTs that have the advantages of both amorphous silicon and polycrystalline silicon on inexpensive, low-temperature plastic substrates. There also is a need for methods to fabricate thin film amorphous/microcrystalline multi-layer silicon solar cells on inexpensive, low-temperature plastic substrates, or any substrate, e.g. glass, known in the art. These needs are addressed by the embodiments of the invention described below and defined by the claims which follow.

### BRIEF SUMMARY OF THE INVENTION

One embodiment of the invention relates to a method for fabricating a silicon-containing film which comprises depositing a thin film of amorphous silicon on a substrate by a plasma-enhanced chemical vapor deposition process in a reaction chamber and converting at least a portion of the amorphous silicon to crystalline silicon by irradiating the film with pulsed laser energy in a hydrogen-containing atmosphere. The hydrogen may be present in the hydrogen-containing atmosphere at a partial pressure of 1 to 600 Torr. Hydrogen gas may be introduced into the reaction chamber to provide the hydrogen-containing atmosphere; alternatively or additionally, a hydrogen plasma may be generated external to the reaction chamber and introduced into the reaction chamber to provide the hydrogen-containing atmosphere.

The substrate may comprise material selected from the group consisting of polyethyleneterephthalate, ethylenechlorotrifluoroethylene, ethylenetetrafluoroethylene, polyethersulfone, polytetrafluoroethylene, high-density polyethylene, polyarylate, polycarbonate, and Mylar®.

The plasma-enhanced chemical vapor deposition process may utilize one or more gases selected from the group consisting of silane, disilane, hydrogen, and argon. The average temperature of the substrate during plasma-enhanced chemical vapor deposition may be less than 100° C. The average temperature of the substrate while irradiating the film with pulsed laser energy may be less than 100° C.

The plasma-enhanced chemical vapor deposition process may utilize diborane and one or more gases selected from the group consisting of silane, disilane, hydrogen, and argon to deposit boron-doped amorphous silicon. Alternatively or additionally, the plasma-enhanced chemical vapor deposition process may utilize phosphene and one or more gases selected from the group consisting of silane, disilane, hydrogen, and argon to deposit phosphorous-doped amorphous silicon. Nickel may be deposited on the thin film of amorphous silicon prior to irradiating the film with pulsed laser energy.

Another embodiment of the invention relates to a composite article which comprises a substrate and a silicon-containing film applied to the substrate by a process which comprises depositing a thin film of amorphous silicon on a substrate by a plasma-enhanced chemical vapor deposition process in a reaction chamber and converting at least a portion of the amorphous silicon to crystalline silicon by irradiating the film with pulsed laser energy in a hydrogen-containing atmosphere. The substrate may comprise material selected from the group consisting of polyethyleneterephthalate, ethylene-chlorotrifluoroethylene, ethylenetetrafluoroethylene, polyethersulfone, polytetrafluoroethylene, high-density polyethylene, polyarylate, polycarbonate, and Mylar®. The silicon-containing film may further comprise phosphorous or boron.

An alternative embodiment of the invention relates to a method of fabricating a multi-layer silicon solar cell structure comprising
(a) depositing a first thin film comprising phosphorous-doped amorphous silicon on a substrate by a plasma-enhanced chemical vapor deposition process;
(b) depositing a second thin film comprising undoped amorphous silicon on at least a portion of the first film by a plasma-enhanced chemical vapor deposition process;
(c) depositing a third thin film comprising boron-doped amorphous silicon on at least a portion of the second film by a plasma-enhanced chemical vapor deposition process to form the multi-layer silicon solar cell structure; and
(d) converting at least a portion of the amorphous silicon in the multi-layer silicon solar cell structure to crystalline silicon by irradiating the film with pulsed laser energy in a hydrogen-containing atmosphere.

A related embodiment includes a composite article comprising a substrate and a multi-layer silicon solar cell structure deposited on the substrate by a process comprising (1) depositing a first thin film comprising phosphorous-doped amorphous silicon on a substrate by a plasma-enhanced chemical vapor deposition process; (2) depositing a second thin film comprising undoped amorphous silicon on at least a portion of the first film by a plasma-enhanced chemical vapor deposition process; (3) depositing a third thin film comprising boron-doped amorphous silicon on at least a portion of the second film by a plasma-enhanced chemical vapor deposition process to form the multi-layer silicon solar cell structure; and (4) converting at least a portion of the amorphous silicon in the multi-layer silicon solar cell structure to crystalline silicon by irradiating the film with pulsed laser energy in a hydrogen-containing atmosphere.

### DETAILED DESCRIPTION OF THE INVENTION

Embodiments of the present invention include a method for fabricating amorphous/polycrystalline silicon thin film transistors (TFTs) with low leakage current from amorphous silicon deposited by plasma enhanced chemical vapor deposition (PECVD) by irradiating amorphous silicon with one or more laser pulses in a hydrogen-containing atmosphere. A method is included for fabricating a multi-layer amorphous/microcrystalline silicon solar cell structure from multi-layer amorphous silicon solar cell structure deposited by PECVD by irradiating it with one or more laser pulses in the presence of hydrogen atmosphere. The PECVD process for depositing amorphous silicon may be carried out at a low temperature, for example, at a temperature of about 100° C.

Amorphous silicon can be deposited at these low temperatures by sputtering, evaporation, or plasma enhanced chemical vapor deposition (PECVD). Amorphous silicon deposited by sputtering and evaporation, however, has been found to have poor electrical properties, and is therefore marginally useful for most TFT and solar cell applications. On the other hand, amorphous silicon deposited by low-temperature PECVD has many desirable electrical properties, and is therefore used for most TFT and solar cell applications.

Amorphous silicon deposited by PECVD at low temperatures contains a significant amount of hydrogen resulting from the deposition process. This hydrogen is required to passivate dangling bonds in amorphous silicon, reduce recombination of electrons and holes, and promote charge transfer. It is believed that the electrical properties of amorphous silicon deposited by PECVD would greatly diminish if the hydrogen content of amorphous silicon were significantly reduced in subsequent processing steps. Therefore, it is important to avoid a significant loss of hydrogen while treating amorphous silicon films. Once the hydrogen content of amorphous silicon is significantly lost during processing, it is difficult to restore unless the film is treated at an elevated temperature (about 200° C.) in hydrogen or hydrogen plasma atmosphere for prolong period of time. It is particularly difficult, if not impossible, to restore hydrogen content of amorphous silicon or polycrystalline silicon film deposited on low-temperature plastic substrates incapable of withstanding a temperature above about 100° C.

Numerous attempts have been made in the past to produce amorphous/polycrystalline silicon TFTs that have the advantages of both amorphous silicon (low reverse leakage current) and polycrystalline silicon (high electron mobility) without the disadvantages of polycrystalline silicon (high reverse leakage current). Most of these attempts concentrated on irradiating an amorphous silicon film deposited by PECVD with one or more laser pulses to partially crystallize the amorphous silicon film followed by exposing the partially crystallized amorphous silicon film to a low temperature (about 200° C.) PECVD hydrogenation process for a short time. These attempts have been successful in producing amorphous/polycrystalline silicon TFTs on plastic substrates capable of withstanding a temperature above about 200° C. Similar attempts have been made to produce amorphous/polycrystalline silicon TFTs on plastic substrates incapable of withstanding a temperature above about 100° C. However, the performance of these TFTs has not been acceptable due to high leakage current. The degradation in performance of these amorphous/polycrystalline silicon TFTs is believed to be related to loss of hydrogen from amorphous silicon/polycrystalline silicon film during laser crystallization and inability to restore hydrogen content by a low temperature (about 100° C.) PECVD hydrogenation process.

Embodiments of the present invention include a method for fabricating amorphous/polycrystalline silicon TFTs with low leakage current from amorphous silicon deposited by PECVD by irradiating the amorphous silicon with one or more laser pulses in the presence of a hydrogen-containing atmosphere. In an alternate embodiment, amorphous silicon may be partially crystallized by irradiating it with one or more laser pulses in the presence of a hydrogen plasma that is generated remotely and introduced into the laser treatment chamber to form a hydrogen-containing atmosphere. The PECVD process for depositing amorphous silicon may be operated at low temperatures, for example, at about 100° C. The use of the hydrogen-containing atmosphere during laser pulse treatment inhibits the loss of hydrogen from the silicon layer during treatment and therefore prevents the complete loss of hydrogen during treatment.

Attempts have been made in fabricating multi-terminal solar cells from amorphous silicon on low-temperature substrates incapable of withstanding sustained processing temperatures of greater than 180° C. These attempts involve depositing amorphous silicon followed by simultaneously crystallizing and doping a part of amorphous silicon by irradiating the amorphous silicon film with one or more laser pulses in the presence of a dopant.

An embodiment of the present invention includes a method of fabricating a multi-layer amorphous/microcrystalline silicon solar cell structure from a multi-layer amorphous silicon solar cell structure deposited by PECVD by irradiating the structure with one or more laser pulses in the presence of hydrogen atmosphere. One embodiment includes a method for depositing by PECVD a multi-layer amorphous silicon solar cell structure comprising a thin bottom layer of phosphorous-doped amorphous silicon, a thin intermediate layer of undoped or intrinsic amorphous silicon, and a thin top layer of boron-doped amorphous silicon layer on a plastic substrate. The method further includes radiation of the multi-layer amorphous silicon solar cell structure with one or more laser pulses in the presence of hydrogen atmosphere to convert the top boron-doped amorphous silicon layer and all or a part of the intermediate intrinsic amorphous silicon layer to boron-doped microcrystalline and intermediate intrinsic microcrystalline silicon layers, respectively. This may be accomplished without exceeding a substrate temperature of about 100° C. and without crystallizing the phosphorous-doped amorphous silicon layer. In an alternative embodiment, the multi-layer amorphous silicon solar cell structure may be irradiated with one or more laser pulses in the presence of a hydrogen plasma that is generated remotely and introduced into the laser treatment chamber. The PECVD process may be operated at low temperatures, for example, at about 100° C.

A wide variety of low-temperature plastic substrates may be used to fabricate silicon TFTs and solar cells according to the embodiments of the present invention. These low-temperature plastic substrates may be selected from polyethyleneterephthalate (PET), ethylenechlorotrifluoroethylene (E-CTFE), ethylenetetrafluoroethylene (E-TFE), polyethersulfone (PES), polytetrafluoroethylene (PTFE), high-density polyethylene, polyarylate (PAR), polycarbonate (PA), Mylar®, and any other plastic material having appropriate physical properties.

The amorphous silicon may be deposited on a plastic substrate at low temperature (for example, below 100° C.) and low pressure in a capacitive-coupled RF plasma CVD reactor using a mixture of silane (or disilane) and hydrogen or a mixture of silane (or disilane), hydrogen, and argon. The boron-doped amorphous silicon may be deposited on a plastic substrate by using a reactant mixture of silane (or disilane), diborane, and hydrogen or a reactive mixture of silane (or disilane), diborane, hydrogen, and argon. Likewise, the phosphorous-doped amorphous silicon may be deposited on a plastic substrate by using a reactive mixture of silane (or disilane), phosphene, and hydrogen or a reactive mixture of silane (or disilane), phosphene, hydrogen, and argon. The amount of hydrogen in the mixture of silane (or disilane) and hydrogen used for depositing doped or undoped amorphous silicon layers may be selected appropriately to avoid the deposition of microcrystalline silicon. Information about deposition and properties of amorphous silicon can be found in a book entitled “Clean Energy from Photovoltaics” edited by Mary D. Archer and Robert Hill and published by Imperial College Press, 2001, Chapter 5 at pp. 199-243 entitled “Amorphous Silicon Solar Cells”, which chapter is incorporated herein by reference.

The amorphous silicon may be partially crystallized by irradiating with one or more pulsed laser using the procedure described in U.S. Pat. No. 5,346,850, which is incorporated herein by reference. It may include treating amorphous silicon with one or more short-pulse of ultra-violet or excimer laser. The excimer laser type may include F2, ArF, KrF, XeCl, and XeF lasers with 157, 193, 248, 308, and 351 nanometer wavelength, respectively. A a XeCl excimer laser having a wavelength of 308 nanometers is most suitable for crystallizing amorphous silicon. An extremely short pulse duration (10 to 50 ns) with energy density varying between 50 and 300 mJ cm⁻² may be used to allow a thin layer of amorphous silicon to melt and recrystallize without damaging the plastic substrate or other layers in the device.

The laser crystallization of amorphous silicon may be carried out in a hydrogen-containing atmosphere in which hydrogen is introduced into the laser treatment chamber at a partial pressure in the range of 1 to 600 torr. Alternatively or additionally, the laser crystallization of amorphous silicon may be carried out in the presence of a hydrogen plasma that is generated remotely and introduced into the laser treatment chamber. The partial pressure of hydrogen in the plasma in the laser treatment chamber may be in the range of 1 to 600 torr. A RF or MW powered unit may be used to generate remotely activated hydrogen plasma.

Amorphous silicon deposited for TFT applications optionally may be doped with a small amount of nickel in desired locations to assist in laser-pulsed crystallization. The small amount of nickel may be deposited using a well-known physical-vapor deposition technique such as sputtering or evaporation. While the above description discloses the deposition and treatment of silicon-containing layers on plastic substrates, the embodiments of the present invention may utilize any desired substrate material.

1. A method for fabricating a silicon-containing film which comprises depositing a thin film of amorphous silicon on a substrate by a plasma-enhanced chemical vapor deposition process in a reaction chamber and converting at least a portion of the amorphous silicon to crystalline silicon by irradiating the film with pulsed laser energy in a hydrogen-containing atmosphere.

2. The method of claim 1 wherein hydrogen is present in the hydrogen-containing atmosphere at a partial pressure of 1 to 600 Torr.

3. The method of claim 1 wherein hydrogen gas is introduced into the reaction chamber to provide the hydrogen-containing atmosphere.

4. The method of claim 1 wherein a hydrogen plasma is generated external to the reaction chamber and introduced into the reaction chamber to provide the hydrogen-containing atmosphere.

5. The method of claim 1 wherein the substrate comprises material selected from the group consisting of polyethyleneterephthalate, ethylenechlorotrifluoroethylene, ethylenetetrafluoroethylene, polyethersulfone, polytetrafluoroethylene, high-density polyethylene, polyarylate, polycarbonate, and Mylar®.

6. The method of claim 1 wherein the plasma-enhanced chemical vapor deposition process utilizes one or more gases selected from the group consisting of silane, disilane, hydrogen, and argon.

7. The method of claim 1 wherein the average temperature of the substrate during plasma-enhanced chemical vapor deposition is less than 100° C.

8. The method of claim 1 wherein the average temperature of the substrate while irradiating the film with pulsed laser energy is less than 100° C.

9. The method of claim 1 wherein the plasma-enhanced chemical vapor deposition process utilizes diborane and one or more gases selected from the group consisting of silane, disilane, hydrogen, and argon to deposit boron-doped amorphous silicon.

10. The method of claim 1 wherein the plasma-enhanced chemical vapor deposition-process utilizes phosphene and one or more gases selected from the group consisting of silane, disilane, hydrogen, and argon to deposit phosphorous-doped amorphous silicon.

11. The method of claim 1 which further comprises depositing nickel on the thin film of amorphous silicon prior to irradiating the film with pulsed laser energy.

12. A composite article which comprises
(a) a substrate; and
(b) a silicon-containing film applied to the substrate by a process which comprises depositing a thin film of amorphous silicon on a substrate by a plasma-enhanced chemical vapor deposition process in a reaction chamber and converting at least a portion of the amorphous silicon to crystalline silicon by irradiating the film with pulsed laser energy in a hydrogen-containing atmosphere.

13. The composite article of claim 12 wherein the substrate comprises material selected from the group consisting of polyethyleneterephthalate, ethylenechlorotrifluoroethylene, ethylenetetrafluoroethylene, polyethersulfone, polytetrafluoroethylene, high-density polyethylene, polyarylate, polycarbonate, and Mylar®.

14. The composite article of claim 12 wherein the silicon-containing film further comprises phosphorous or boron.

15. A method of fabricating a multi-layer silicon solar cell structure comprising
(a) depositing a first thin film comprising phosphorous-doped amorphous silicon on a substrate by a plasma-enhanced chemical vapor deposition process;
(b) depositing a second thin film comprising undoped amorphous silicon on at least a portion of the first film by a plasma-enhanced chemical vapor deposition process;
(c) depositing a third thin film comprising boron-doped amorphous silicon on at least a portion of the second film by a plasma-enhanced chemical vapor deposition process to form the multi-layer silicon solar cell structure; and
(d) converting at least a portion of the amorphous silicon in the multi-layer silicon solar cell structure to crystalline silicon by irradiating the film with pulsed laser energy in a hydrogen-containing atmosphere.

16. A composite article comprising
(a) a substrate; and
(b) a multi-layer silicon solar cell structure deposited on the substrate by a process comprising
(1) depositing a first thin film comprising phosphorous-doped amorphous silicon on a substrate by a plasma-enhanced chemical vapor deposition process;
(2) depositing a second thin film comprising undoped-amorphous silicon on at least a portion of the first film by a plasma-enhanced chemical vapor deposition process;
(3) depositing a third thin film comprising boron-doped amorphous silicon on at least a portion of the second film by a plasma-enhanced chemical vapor deposition process to form the multi-layer silicon solar cell structure; and
(4) converting at least a portion of the amorphous silicon in the multi-layer silicon solar cell structure to crystalline silicon by irradiating the film with pulsed laser energy in a hydrogen-containing atmosphere.
